(19) United States
(12) Patent Application Publication
(10) Pub. No.: US 2011/0252289 A1
(43) Pub. Date: Oct. 13, 2011

(54) ADJUSTING STORAGE DEVICE PARAMETERS BASED ON RELIABILITY SENSING

(75) Inventors: Ara Patapoutian, Hopkinton, MA (US); Bruce Douglas Buch, Westborough, MA (US)

(73) Assignee: Seagate Technology LLC, Scotts Valley, CA (US)

(21) Appl. No.: 12/756,974

(22) Filed: Apr. 8, 2010

(51) Int. Cl. H03M 13/05; G06F 11/10

(52) U.S. Cl. 714/763; 714/E11.034

(57) ABSTRACT

In general, this disclosure is directed to techniques for adjusting storage device parameters based on reliability sensing. According to one aspect, a method includes retrieving a codeword from a plurality of data blocks within a storage device, wherein each of the data blocks stores a respective portion of the codeword, generating a detected value for a bit within a first portion of the codeword based on information related to a reliability of a data block associated with the first portion, and performing error correction on a second portion of the codeword based on the detected value for the bit within the first portion of the codeword. According to another aspect, a method includes obtaining information related to a reliability of a data block within a storage device, and adjusting a data capacity for the storage device based on the information related to the reliability of the data block.

### SUMMARY

According to one aspect of the invention, a method includes retrieving a codeword from a plurality of data blocks within a storage device, wherein each of the data blocks stores a respective portion of the codeword. The method further includes generating a detected value for a bit within a first portion of the codeword based on information related to a reliability of a data block associated with the first portion. The method further includes performing error correction on a second portion of the codeword based on the detected value for the bit within the first portion of the codeword.

According to another aspect of the invention, a method includes retrieving a codeword from a plurality of data blocks within a storage device, wherein each of the data blocks stores a respective portion of the codeword. The method further includes performing codeword portion-specific error corrections on the portions of the codeword to generate codeword portion-specific error correction information. The method further includes performing codeword-level error correction on the codeword based on the codeword-specific error correction information and information related to a reliability of each of the data blocks.

According to another aspect of the invention, a method includes retrieving raw data bits for a codeword stored within a data block of a block storage device. The method further includes retrieving information related to a reliability of the data block, wherein the information related to the reliability of the data block comprises at least of an amount of time to perform an erase operation for the data block, an amount of time to perform a program operation for the data block, errors that occur with respect to the data block, and an error log for the data block. The method further includes generating soft detected values for the raw data bits based on soft information bits contained within the raw data values and information related to a reliability of the data block. The method further includes performing error correction for the raw data bits based on the soft detected values.

According to another aspect of the invention, a device includes a controller configured to retrieve a codeword from a plurality of data blocks within the storage device, wherein each of the data blocks stores a respective portion of the codeword. The device further includes a detector configured to generate a detected value for a bit within a first portion of the codeword based on information related to a reliability of a data block associated with the first portion. The device further includes a decoder configured to perform error correction on a second portion of the codeword based on the detected value for the bit within the first portion of the codeword.

According to another aspect of the invention, a device includes a controller configured to retrieve a codeword from a plurality of data blocks within the storage device, wherein each of the data blocks stores a respective portion of the codeword. The device further includes a plurality of inner decoders configured to perform codeword portion-specific error corrections on the portions of the codeword to generate codeword portion-specific error correction information. The device further includes an outer decoder configured to perform codeword-level error correction on the codeword based on the codeword-specific error correction information and information related to a reliability of each of the data blocks.

According to another aspect of the invention, a device includes a controller configured to retrieve raw data bits for a codeword stored within a data block of the storage device and to retrieve information related to a reliability of the data block, wherein the information related to the reliability of the data block comprises at least of an amount of time to perform an erase operation for the data block, an amount of time to perform a program operation for the data block, errors that occur with respect to the data block, and an error log for the data block. The device further includes an error correction module configured to generate soft detected values for the raw data bits based on soft information bits contained within the raw data bits and information related to a reliability of the data block, and perform error correction for the raw data bits based on the soft detected values.

According to another aspect of the invention, a method includes receiving information related to a reliability of a data block within a storage device, wherein the information related to the reliability of the data block comprises at least one of an amount of time to perform an erase operation for the data block and an amount of time to perform a program operation for the data block. The method further includes adjusting a data capacity for the storage device based on the information related to the reliability of the data block.

According to another aspect of the invention, a device includes a reliability module configured to receive information related to a reliability of a data block within the storage device, and adjust a data capacity for the storage device based on the information related to the reliability of the data block, wherein the information related to the reliability of the data block comprises at least one of an amount of time to perform an erase operation for the data block and an amount of time to perform a program operation for the data block.

These and various other features and advantages will be apparent from a reading of the following detailed description.

### BRIEF DESCRIPTION OF DRAWINGS

FIG. 1 is a block diagram illustrating an example storage device according to one aspect of the present invention.

FIG. 2 is a block diagram of an example reliability module according to one aspect of the present invention.

FIG. 3 is a conceptual diagram of an example storage unit according to one aspect of the present invention.

FIG. 4 is a conceptual diagram of an example storage chip according to one aspect of the present invention.

FIG. 5 is a block diagram of an example storage device that includes an error correction module according to one aspect of the present invention.

FIG. 6 is a block diagram of another example storage device that includes an error correction module according to one aspect of the present invention.

FIG. 7 is a flow diagram illustrating an example method for adjusting a data capacity of a storage device based on reliability information according to one aspect of the present invention.

FIG. 8 is a flow diagram illustrating an example method for performing error correction based on reliability information according to one aspect of the present invention.

FIG. 9 is a flow diagram illustrating another example method for performing error correction based on reliability information according to one aspect of the present invention.

FIG. 10 is a flow diagram illustrating another example method for performing error correction based on reliability information according to one aspect of the present invention.

FIG. 11 is a flow diagram illustrating another example method for performing error correction based on reliability information according to one aspect of the present invention.

### DETAILED DESCRIPTION

In general, this disclosure is directed to techniques for adjusting storage device parameters based on reliability sensing. In some examples, a reliability sensing module may determine the reliability or aging of a storage device based on one or more input parameters that convey information related to the reliability of a data block or storage device. Based on this determination, the reliability sensing module may adjust one or more storage device configuration parameters to improve endurance of the device and/or to maintain appropriate levels of reliability even though the device may be aged or degraded.

In some examples, the reliability module may decrease an Error Correction Code (ECC) code rate when the reliability module senses that the device or a particular data block within the device has reached a certain age or has exhibited a certain level of reliability loss. For example, the reliability module may reallocate storage cells that were originally operating as data storage cells (i.e., non-parity storage cells) to now operate as parity storage cells (e.g., ECC storage cells). By increasing the number of parity storage cells relative to the number of data storage cells, the effective ECC code rate may be lowered thereby increasing the reliability of the storage device.

In additional examples, the reliability module may decrease the alphabet size of storage cells within a storage device or a particular data block when the reliability module senses that the device or the data block has reached a certain age or has exhibited a certain level of reliability loss. For example, the reliability module may reduce the alphabet size by reconfiguring a set of storage cells to use only a subset of the maximum alphabet size of the storage cells. In some examples, the maximum alphabet size of the storage cells may be the maximum alphabet size for which the cells were originally configured at the time of manufacture. For certain storage device, such as flash devices for example, reducing the alphabet size may increase the noise margins for the storage cells, and thereby increase the reliability of the storage device.

In further examples, the reliability sensing techniques of this disclosure may be utilized to enhance error correction functions within a storage device. For example, the reliability information may be used to provide reliability-sensitive soft information (e.g., soft detected values) to an error correction code (ECC) decoder. In some examples, the reliability information may be used to increase or attenuate a soft detected value generated by a probabilistic function (e.g., a log-likelihood ratio (LLR)). In some examples, a logical block or codeword may be dispersed across several different storage devices (e.g., flash chips). In such examples, device-specific reliability information may be used to generate device-specific soft detected values. An ECC decoder may then be able to more accurately identify which bits within a logical block or codeword are more or less reliable depending on the reliability of the device from which the data bits were read. By providing reliability-sensitive soft information, the performance of the ECC decoder may be improved thereby improving the overall reliability of the storage device.

In some examples, indicators of reliability may include the number of erase operations that have occurred for a particular data block (e.g., a flash erasure block), or the number of program cycles that have occurred for a particular data block (e.g., a flash page). In some storage devices, such as flash devices for example, the number of program and/or erase cycles may be related to device performance and aging. With conventional devices, a user may stop using the device after the program/erase count has reached a certain threshold level. The techniques in this disclosure, however, allow a user to continue using the device even after the program/erase count exceeds the threshold aging level for conventional devices.

In additional examples, indicators of reliability may include the amount of time taken by the storage device to perform an erase operation or the amount of time taken by the storage device to perform a program operation. In some storage devices, the amount of time taken to perform an erase or program cycle may increase with age. For example, in some flash devices, as the device ages, the amount of retries that need to occur in order to perform a successful program or erase operation may increase, which in turn may cause the amount of time taken to perform the erase and/or program cycles to increase. In other example devices, the amount of time taken to perform an erase or program cycle may decrease with age. In any case, the amount of time to perform such operations may be used as an indicator of reliability from which various operating parameters may be adjusted to compensate for an aging or less reliable device.

In further examples, an error log generated for a particular device or data block, and/or a number of errors that have occurred with respect to the data block may be used as an indicator of reliability. In some examples, the error log may be extracted from metadata that is stored within a data block of the storage device. The error information provided by an error log may be a useful indicator of loss of reliability.

Although a degraded or aged flash device may still hold information, such a device may have less reliability than a new flash device. The reliability techniques described herein may extend the life of a device by sensing the aging of the device, and adjusting the configuration of the storage device to improve one or both of reliability and endurance of the storage device.

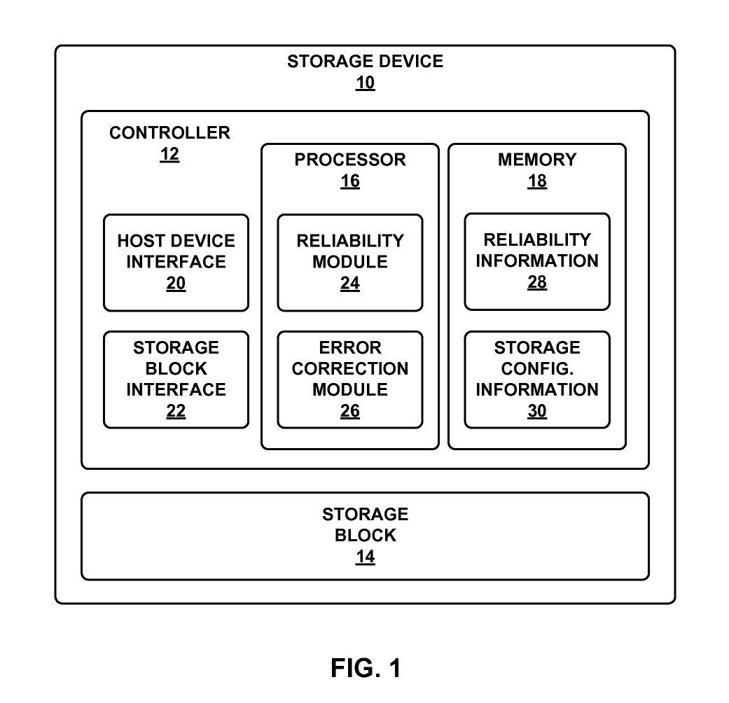

FIG. 1 is a block diagram illustrating an example storage device 10 according to one aspect of the present invention. Storage device 10 is configured to store and retrieve data upon instructions from a host device. Storage device includes a controller 12 and a storage block 14. In some examples, storage device 10 may be a block storage device that provides read and/or write access to data in logical blocks. In some examples, storage device 10 may be a solid state drive (e.g., a flash drive), a hard drive, or any other type of data storage device.

Controller 12 is configured to handle requests received from a host device to store data to and retrieve data from storage block 14. Controller includes a processor 16, a memory 18, a host device interface 20, and a storage block interface 22. Controller 12 is communicatively coupled to storage block 14 via storage block interface 22. Controller 12 is also communicatively coupled to a host device via host device interface 20.

Processor 16 is configured to control operations of storage device 10 for writing data to and reading data from storage block 14. Processor 16 includes a reliability module 24 and an error correction module 26. Processor 16 is communicatively coupled to memory 18, host device interface 20, and storage block interface 22. In some examples, processor 16 may also be communicatively coupled to storage block 14.

According to this disclosure, reliability module 24 is configured to sense the reliability of all or a portion of storage block 14, and to adjust configuration parameters for storage block 14 based on the sensed reliability. In some examples, reliability module 24 may determine a reliability metric, which in turn may be used to adjust the configuration parameters. The reliability metric, in some cases, may be correlated with the aging of storage device 10.

Reliability module 24 may be configured to obtain information related to a reliability of a data block (i.e., reliability information) within a storage device, and adjust a data capacity for the storage device based on the information related to the reliability of the data block. In some examples, reliability module 24 may adjust the data capacity by adjusting the data capacity of one or more particular storage units within storage block 14 of storage device 10. In some examples, the reliability information may include at least one of an amount of time to perform an erase operation for the data block, and an amount of time to perform a program operation for the data block.

As used herein, a raw data capacity or physical data capacity may refer to a maximum amount of storage space allocated within the storage device for the storage of user data, a maximum amount of user data that the storage device is capable of storing, a maximum number of logical blocks the storage device is capable of storing, and/or the number of physical blocks within the storage device. User data may, in some examples, refer to data that is transferred by a host device to a storage device for storage. Non-user data, in some examples, may refer to data that is used internally by the storage device for storing and retrieving data (e.g., ECC data, metadata).

A host data capacity, as used herein, may refer to an advertised maximum amount of storage space allocated within the storage device for the storage of user data, an advertised maximum amount of user data that the storage device is capable of storing, an advertised maximum number of logical blocks the storage device is capable of storing, a maximum amount of user data to which a host device is able to read or write data, a total number of logical blocks within a logical block address space provided by the storage device, and/or a total amount of logical storage space (e.g., data storage space as seen from the host device) within a storage device.

The host data capacity may, in some examples, be the data capacity that is advertised by the storage device to the host device as a storage capacity for the storage device. In contrast, the raw data capacity may, in such examples, be the actual physical amount of user data storage space within the storage device. In other words, the raw data capacity may, in some examples, be independent of host data capacity for the device. For example, the raw data capacity may refer to the maximum amount of user data a storage device is physically capable of storing, which may be greater than the advertised maximum amount of user data the storage device is logically capable of storing.

In some examples, storage device 10 may use over-provisioning techniques to allow for more efficient program/erase operations and/or garbage collection. In such examples, the raw data capacity may be greater than the host data capacity. For example, the number of physical data blocks in storage device 10 may be greater than the number of logical blocks within the logical block address space provided by storage device 10. The logical block address space, in some examples, may refer to the logical blocks to which a host device expects to be able to read and write data. Thus, in such examples, even if a physical block is allocated for each logical block within the logical block address space, storage device 10 will still contain additional “unallocated” physical blocks. In other words, over-provisioning techniques may provide extra physical data blocks over and above the number of logical blocks within a logical block address space. These extra physical blocks may be referred to, herein, as a “stretch area.”

Reliability module 24 may adjust the data capacity by adjusting the raw data capacity of one or more storage units within storage bock 14. In some examples, reliability module 24 may use variable ECC output 48 and/or variable alphabet output 50 to reduce the raw data capacity when reliability module 24 senses an aging storage unit or loss of reliability. For example, reliability module 24 may use the variable ECC output 48 to reduce the number of data cells allocated as user data cells (e.g., by reallocating such cells to operate as ECC cells), but maintain the alphabet size of each user data cell (e.g., maintain the number of bits each user data cell is capable of storing). In other examples, reliability module 24 may use the variable alphabet output 50 to reduce the alphabet size for each user data cell, but maintain the number of data cells allocated as user data cells within the storage units. In additional examples, reliability module 24 may reduce the raw data capacity by adjusting both variable ECC output 48 and variable alphabet output 50.

In examples where storage device 10 uses over-provisioning techniques, when reliability module 24 reduces the raw data capacity, reliability module 24 may utilize the stretch area (e.g., unallocated physical data blocks) to store additional user data. For example, reliability module 24 may direct one or more storage units within storage block 14 to increase the amount of physical storage space (e.g., physical blocks or portions thereof) allocated for each logical block. In such examples, storage block 14 may utilize one or more of the physical blocks within the stretch area to increase the amount of physical storage space allocated from each logical block. In other words, the stretch area may be used to store the data that is displaced from other physical blocks that now have a reduced raw data capacity. In this manner, reliability module 24 is capable of reducing the raw data capacity, but maintaining the host data capacity.

In some examples, reliability module 24 may adjust the data capacity by adjusting an amount of storage space allocated for error correction functions for one or more storage units within storage block 14. In additional examples, reliability module 24 may adjust the data capacity by adjusting an alphabet size for storage cells of one or more storage units within storage block 14. For example, reliability module 24 may adjust a number of data bits that can be stored within a single storage cell for each storage cell within storage block 14. In further examples, reliability module 24 may adjust the data capacity by allocating additional physical blocks or portions thereof to each logical block stored within storage device 10. In the manner, when the aging of storage device 10 deceases the reliability of the storage device, the raw data capacity of storage units within storage block 14 may be reduced to maintain and/or improve reliability levels.

According to this disclosure, error correction module 26 is configured to perform error correction on raw data based on side information associated with the reliability of data blocks from which the raw data is retrieved. In some examples, error correction module 26 may increase or attenuate log-likelihood ratios (LLR) based on the side information. In this manner, the error correction process may take into account aging and other reliability indicators to increase error correction performance.

In some examples, error correction module 26 may be configured to generate a detected value for a bit within a first portion of the codeword based on information related to a reliability of a data block associated with the first portion, and perform error correction on a second portion of the codeword based on the detected value for the bit within the first portion of the codeword.

In further examples, error correction module 26 may be configured to perform codeword portion-specific error corrections on the portions of the codeword to generate codeword portion-specific error correction information, and perform error correction on the codeword based on the codeword-specific error correction information and information related to a reliability of each of the data blocks

In additional examples, error correction module 26 may be configured to generate soft detected values for raw data bits retrieved from storage block 14 based on soft information bits contained within the raw data bits and information related to a reliability of the data block (i.e., reliability information), and perform error correction for the data values based on the soft detected values.

Processor 16 may include one or more programmable processors. In some examples, the one or more programmable processors may have instructions stored therein that when executed by the one or more processors perform any of the techniques described in this disclosure. It should be noted that, although reliability module 24 and error correction module 26 are depicted as being part of processor 16, either of these modules may be located outside or processor 16 or outside of controller 16.

Memory 18 is configured to store information for use by controller 12 of storage device 10. Memory 18 includes reliability information 28 and storage configuration information 30. Memory 18 is communicatively coupled to processor 16, host device interface 20, and storage block interface 22. In some examples, memory 18 may also be communicatively coupled to storage block 14.

Reliability information 28 includes information related to the reliability of a data block or storage unit within storage block 14. In some examples, reliability information 28 may be an indicator of the aging of storage device 10. Reliability information 28 may include, in some examples, one or more of the following: information related to an erase cycle count for a data block or storage unit, information related to a program cycle count for a data block or storage unit, information related to an amount of time to perform an erase operation for a data block or storage unit, information related to an amount of time to perform a program operation for a data block or storage unit, information related to errors that occur with respect to a data block or storage unit, and an error log for a data block or storage unit. In some examples, reliability information 28 may be stored within storage block 14 and/or within a host device in addition to or in lieu being stored in memory 18.

Storage configuration information 30 includes configuration parameters for configuring various storage aspects of storage block 14. In some examples, storage configuration information 30 may include configuration parameters related to a dynamic data capacity (e.g., raw data capacity) for storage block 14 or for particular storage units within storage block 14. In additional examples, storage configuration information 30 may include configuration parameters related to a dynamic storage allocation that specifies an amount of storage space allocated for user data bits verses an amount of storage space allocated for parity bits within a particular data block or storage unit of storage block 14. In further examples, storage configuration information 30 may include configuration parameters related to a dynamic ECC code rate for a particular data block or storage unit of storage block 14. In additional examples, storage configuration information 30 may include configuration parameters related to a dynamic alphabet size for storage cells for one or more storage cells, data blocks or storage units within storage block 14. In some examples, storage configuration information 30 may be stored within storage block 14 and/or within a host device in addition to or in lieu of being stored in memory 18.

Memory 18 may be implemented, in some examples, with a volatile storage device. For example, memory 18 may be implemented as random access memory (RAM) such as synchronous dynamic random access memory (SDRAM), embedded dynamic random access memory (eDRAM), static random access memory (SRAM), or the like.

Host device interface 20 is configured to provide communications between storage device 10 and a host device that issues data access commands to storage device 10. In some examples, host device interface 20 may deliver control information such as read, program, and erase commands to processor 16 for processing. In additional examples, host device interface 20 may deliver data between processor 16, storage block 14 and/or the host device as part of read, program, and erase command. In some examples, the data delivered may be in units of logical blocks.

Host device interface 20 is communicatively coupled to processor 16 and memory 18. In some examples, host device interface 20 may also be communicatively coupled to storage block interface 22. Host device interface 20 is also communicatively coupled to a host device. In some examples, host device interface may communicate according to protocols such as, for example, Advanced Technology Attachment (ATA), Serial Advanced Technology Attachment (SATA), Small Computer System Interface (SCSI), Serial Attached SCSI (SAS), Internet Small Computer System Interface (iSCSI), Fibre Channel (FC), or any other means or protocol through which a host device may communicate with a data storage device.

Storage block interface 22 is configured to provide communications between controller 12 and storage block 14. In some examples, storage block interface 22 may deliver data between storage block 14, processor 16 and/or host device interface 20. Storage block interface 22 may execute read, write, program and/or erase commands issued by controller 12. Storage block interface 22 is communicatively coupled to processor 16 and memory 18. In some examples, storage block interface 22 may also be communicatively coupled to host device interface 20.

Storage block 14 is configured to store data for storage device 10. In some examples, storage block 14 may include one or more storage units. The storage units, in some examples, may be block storage devices that include one or more physical data blocks. Storage block 14 is communicatively coupled to storage device interface 22. In some examples, storage block 14 may be communicatively coupled to processor 16 and/or memory 18. Each of the storage units may provide reliability information or side information to reliability module 24 and/or error correction module 26. In some examples, storage block 14 may include one or more storage chips (e.g., flash chips and/or flash die).

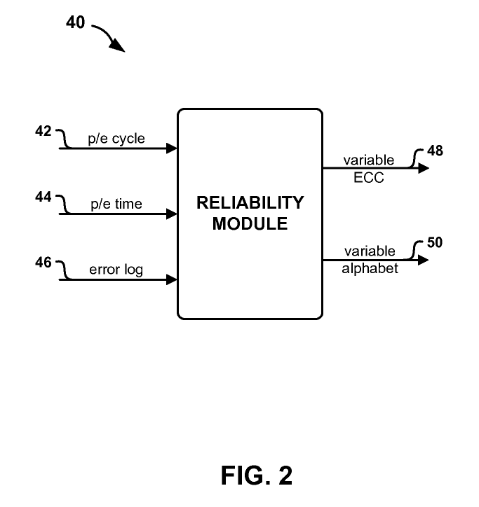

FIG. 2 is a block diagram of an example reliability module 40 according one aspect of the present invention. In some examples, reliability module 40 may correspond to reliability module 24 of storage device 10 illustrated in FIG. 1.

Reliability module 40 is configured to receive information related to a reliability of a data block within the storage device, and to adjust a data capacity for storage block 14 or one or more storage units therein based on the information related to the reliability of the data block. Reliability module 40 includes an program/erase (p/e) cycle input 42, an p/e time input 44, an error log input 46, a variable error correction code (ECC) output 48, and a variable alphabet output 50.

The terms side information and reliability information, as used herein, may refer to any information that indicates or is effected by the aging of a storage device. In some examples, the side information and reliability information may include any combination of information provided by one or more of p/e cycle input 42, p/e time input 44, and error log input 46. The reliability information may include information related to the reliability or aging of one or more particular data blocks and/or storage cells within a storage device. For example, the reliability information may be associated with a particular data block or storage unit within storage block 14. Reliability module 40 is configured to determine a level of aging or reliability of a data cell, data block or storage unit based on information provided by p/e cycle input 42, p/e time input 44, and/or error log input 46. The level of aging or reliability determined by reliability module 40 may be referred to herein as a reliability metric.

Reliability module 40 may be configured to compare the reliability metric to a threshold. If the reliability metric is greater than the threshold, then reliability module 40 may determine that the data block or storage unit within storage device 10 has a high enough level of reliability that countermeasures do not need to be taken to maintain appropriate reliability levels. Otherwise, if the reliability metric is not greater than the threshold, then reliability module 40 may determine that countermeasures need to be taken to maintain appropriate reliability levels. Countermeasures taken by reliability module 40 may include adjusting the ECC code rate via variable ECC output 48 and/or adjusting the alphabet size via variable alphabet output 50.

In some cases, appropriate reliability levels may based on a maximum allowable probability of an unsuccessful read, write, program, or erase operation occurring. For example, the appropriate reliability level may be based on a certain level of reliability guaranteed by a manufacturer for a storage unit having an age lower than that of the currently operating storage unit. In other examples, the appropriate reliability level may be a predetermined reliability level built into storage device 10 at the time of manufacture. In further examples, the appropriate reliability level may be a programmable variable for storage device 10 that may be programmed by a host device that has access to storage device 10.

In some examples, reliability module 40 may switch from a first mode of operation to a second mode of operation when reliability module 40 determines that the aging and/or reliability of a storage unit or data block is greater than a threshold. In such examples, the second mode of operation may, for example, have a lower raw data storage capacity relative to the first mode of operation. In further examples, the second mode of operation may have a greater amount of storage cells within a given data block allocated as ECC cells (i.e., a lesser amount of cells allocated as data cells). In additional examples, the second mode of operation may have a lower ECC code rate relative to the first mode of operation. In further examples, the second mode of operation may have a lower alphabet size (i.e., number of bits stored per cell) relative to the first mode of operation. In this manner, reliability module 40 allows an aging storage device to maintain appropriate reliability levels even at times when a conventional storage device would experience a significant reduction in reliability due to aging.

In some examples, p/e cycle input 42, p/e time input 44, and/or error log input 46 may each be represented by a binary number that includes one or more bits. In some examples, each of inputs 43, 44 and 46 may be represented by only a single bit. In any case, reliability module 40 may determine a reliability metric based on some combination of the input bits or numbers. For example, reliability module 40 may use statistical processing to determine an appropriate reliability metric. The statistical processing, in some examples, may use historical reliability information in addition to instantaneous reliability information to determine a current reliability metric for a data block and/or storage unit. In further examples, reliability module 40 may calculate a weighted sum of one or more of the reliability information inputs to generate the reliability metric.

In some examples, reliability module 40 may partition a range of possible erase cycle counts and/or a range of possible program cycle counts into a plurality of intervals (e.g., N intervals). Reliability module 40 may then determine into which interval the current erase cycle count and/or current program cycle count falls, and decrease the ECC code rate by an interval-specific amount based on the determined interval. In additional examples, reliability module 40 may attenuate (e.g., decrease) or saturate (e.g., increase) soft detected values based on the determined interval.

In further examples, reliability module 40 may partition a range of possible erase times and/or a range of possible program time into a plurality of intervals (e.g., N intervals). Reliability module 40 may then determine into which interval the current erase time and/or program time falls, and decrease the ECC code rate by an interval-specific amount based on the determined interval. In additional examples, reliability module 40 may attenuate or saturate soft detected values based on the determined interval.

Reliability module 40 may be configured to adjust one or more storage parameters for a block storage device based on the reliability metric and/or side information. For example, reliability module 40 may be configured to adjust a data capacity of one or more storage units within a block storage device.

In some examples, reliability module 40 may adjust the data capacity by using the variable ECC output 48 to adjust an amount of storage space allocated for data bit storage and parity bit storage. As used herein, a codeword may refer to collection of bits that includes data bits (i.e., non-parity bits) and parity bits (e.g., ECC bits). Thus, if reliability module 40 detects an aging device or loss of reliability, reliability module 40 may use ECC output 48 to reallocate storage space within a storage unit of storage device 10. For example, reliability module 40 may reallocate data storage cells to operate as ECC storage cells.

The ECC code rate, as used herein, may refer to the quotient of data bits divided by length of the codeword. The length of the codeword may be the sum of the data bits and parity bits. Therefore, by increasing the amount of parity storage space within a data block relative to the amount of non-parity storage space, reliability module 40 effectively decreases the ECC code rate. In this manner, reliability module 40 may dynamically adjust the ECC code rate as a function of the reliability information.

In some examples, reliability module 40 may use variable ECC output 48 to adjust the data/ECC storage allocation by increasing and/or decreasing a codeword length for codewords stored within the storage device based on the reliability information. In additional examples, reliability module 40 may use variable ECC output 48 to adjust data/ECC storage allocation by reallocating data storage cells within a storage device to operate as error correction storage cells or reallocating error correction storage cells to operate as data storage cells. In any case, reliability module 40 may use variable ECC output 48 to adjust the effective ratio of data cells to ECC cells within a data block of a storage device.

In some examples, data compression may be used to provide additional ECC storage cells. For example, reliability module 40 may determine that a storage unit is aging and that the ECC code rate should be decreased. In such a case, reliability module 40 may instruct the device to commence performance of data compression or to perform a greater degree of data compression to free up storage space to allow for the use of additional ECC cells. In this manner, the ECC code rate may be increased while maintaining the mapping between logical blocks and physical blocks within storage device 10.

In additional examples, reliability module 40 may adjust the data capacity by using the variable alphabet output 50 to adjust a number of data bits that can be stored within a single storage cell for each storage cell within a storage unit. For example, in a block storage device, such as flash devices and/or solid state drives, the storage cells may be configured to store a variable number of bits. In some cases, floating gate transistors with a variable number of voltage levels and/or voltage thresholds may be used. In some examples, reliability module 40 may use variable alphabet output 50 to switch between a single-level cell (SLC) mode of operation and a multi-level cell (MLC) mode of operation. In another example, adjusting the number of data bits stored within a single storage cell may include switching between modes of operation where each mode uses a different number of voltage levels or thresholds for the cells. In any case, reliability module 40 may use variable alphabet output 50 to dynamically adjust the alphabet size of storage cells within the storage device based on reliability information.

In some examples, if reliability module 40 senses that a device has reached a certain threshold of aging or loss of reliability, reliability module 40 may reduce the alphabet size of cells within a multi-level cell (MLC) block storage device, and thus, use a subset of the maximum alphabet size of the MLC block storage device. This may allow the reuse of a degraded MLC-2 bit device, e.g., to be used as an SLC device.

In some examples, reliability module 40 may adjust the variable ECC output 48 and/or variable alphabet output 50 based on one or more of the reliability parameters (e.g., p/e-cycles count 42, p/e time 44, error log 46) independent of other reliability parameters. In additional examples, if any of the parameters indicate unreliable cells or an aging device, reliability module 40 may adjust one of outputs 48, 50. In further examples, reliability sensing module 40 may adjust outputs 48, 50 only if all parameters indicate unreliable cells or an aging device.

In some examples, if reliability module 40 senses an aging device or a loss of reliability, reliability module 40 may maintain the alphabet size of data blocks (e.g., hold variable alphabet 50 stable), and reduce the ECC code rate. In additional examples, if reliability module 40 senses an aging device or a loss of reliability, reliability module 40 may keep the ECC code rate uniform (e.g., hold variable ECC output 48 stable), and reduce the alphabet size of impaired storage cells. In further examples, reliability module 40 may reduce the ECC code rate and the alphabet size to provide additional flexibility.

Reliability module 40 may, in some examples, operate in conjunction with error correction module 26 to adjust parameters related to error correction based on the reliability information as described later in this disclosure. For example, in storage devices where soft information is not already available, reliability module 40 may generate soft information for use by a decoder (e.g., an ECC unit). In cases where soft information is already available, reliability module 40 may modify the soft information (e.g., saturate or attenuate) the soft information based on the reliability information. In such examples, reliability module 40 may have a third output (not shown) that generates soft information for a decoder that performs error correction.

As already discussed above, p/e cycle input 42, p/e time input 44, and/or error log input 46 provide device aging information and/or reliability information to reliability module 40. In some examples, p/e cycle input 42 may include information related to a number of erase cycles (e.g., erase operations) that have occurred for one or more data blocks within a storage device and/or information related to a number of program cycles (e.g., program operations) that have occurred for one or more data blocks within a storage device. For example, such information may include the total number of erase and/or program cycles that have occurred over the lifetime of the storage device with respect to one or more data blocks. In some examples, the p/e cycle input 42 may be a single bit which is reset when the number of erase and/or program cycles is below a particular threshold, and set when the number of erase and/or program cycles is above a particular threshold.

In some examples, storage device 10 may utilize a wear leveling algorithm that keeps track of program/erase cycles (p/e-cycles). In such an algorithm, blocks with larger p/e-cycle counts are generally deemed to be less reliable, and may eventually be retired. According to this disclosure, rather than using p/e-cycles to merely retire blocks, reliability module 40 may take appropriate actions (e.g., adjusting variable ECC output 48 and/or variable alphabet output 50) to improve reliability and maintain operation of the blocks having larger p/e-cycle counts.

In some examples, p/e time input 44 may include information related to an amount of time to perform an erase cycle and/or information related to an amount of time to perform a program cycle within a storage device. For example, such information may include a time duration (e.g., an amount of time used by the storage device) for performing the most recent erase and/or program operation. In further examples, such information may include a moving average of time durations for performing the most recent erase and/or program operations. The moving average may be based on a particular time window or on a window defined by a particular number of the most recent erase and/or program operations.

In some examples, p/e time input 44 may be a single bit which is reset when the time duration for erase and/or program operations is above a certain threshold, and set when the time duration for erase and/or program operations is below a certain threshold. In additional examples, p/e time input 44 may include one or both of the following parameters: (1) a parameter indicating the time it takes to erase a data block (tₑ); or (2) a parameter indicating the time it takes to program a data block (tₚ).

In some examples, a storage device (e.g., a flash storage device) may have an output signal that indicates if the storage device is in a “Ready” state or a “Busy” state (e.g. a Ready/Busy signal). After a program or erase command has been issued, the storage device may drive the signal to a “Busy” state to indicate that the storage device is busy executing the operation. After the operation has completed, the storage device may drive the signal to a “Ready” state indicating the operation is complete. In such examples, reliability module 40 may, in some examples, measure tₚ and/or tₑ by clearing a counter when a program or erase operation is issued and incrementing the counter while the output signal indicates the device is “Busy,” and ceasing to increment the counter when the output signal indicates the device is “Ready.”

In some examples, storage device 10 may include a register (e.g., a flash device register) that can be polled to determine if the device is “Busy” or “Ready.” When polled, the register may return a first value if the device is “Busy” and a second value if the device is “Ready.” In such examples, reliability module 40 may measure tₚ and tₑ by clearing a counter when a program or erase operation is issued and incrementing the counter until the value read from the status register indicates completion (i.e., “Ready”).

In some examples, programming and erasing may be asymmetric operations. The erase operation may change all cells in an erase block to a logic “1” value, and a program operation may change the selected cells that were previously erased (i.e., logic “1”) to logic “0” values. In such examples, an erase operation may be complete, in some examples, only when all the previously existing logic “0” values in an erase block are changed to logic “1” values. Similarly, in such examples, a program operation may be complete, in some examples, only when all the selected cells that were previously erased (logic “1” values) are changed to (logic “0” values).

In some examples, reliability module 40 may obtain information related to the health of a NAND cell by measuring the time it takes to erase a block or to program a page (tₑ, tₚ). In such examples, a longer (tₑ, tₚ) interval may indicate that the cells belonging to that particular block have become less reliable. In other examples, a shorter (tₑ, tₚ) interval may indicate that the cells belonging to that particular block have become less reliable.

In some examples, error log input 46 may include information related to a number of errors that have occurred for one or more data blocks within a storage device. In some examples, the number of errors may refer to a number of read errors for one or more particular data blocks. In additional examples, the number of errors may refer to a number of write errors for one or more particular data blocks. The number of errors may refer to any combination of read errors, write errors, program errors and/or erase errors for one or more particular data blocks. In further examples, such information may include a moving average of the number of errors for recent read, program and/or erase cycles. The moving average may be based on a particular time window or on a window defined by a particular number of the most recent erase and/or program operations. In some examples, the error log input 46 may be a single bit which is reset when the number of errors is above a particular threshold, and set when the number of erase and/or program cycles is below a particular threshold. In some examples, if a block has been read, an error log generated by the ECC unit may be stored in the metadata to reflect the health of a particular block.

The reliability information provided by p/e cycle input 42, p/e time input 44, and/or error log input 46 may, in some examples, be stored as part of reliability information 28 in memory 18 of storage device 10. In additional examples, the reliability information provided by p/e cycle input 42, p/e time input 44, and/or error log input 46 may be stored in storage block 14 of storage device 10, e.g., as metadata for a data block within storage block 14. In further examples, the reliability information provided by p/e cycle input 42, p/e time input 44, and/or error log input 46 may be stored in a host device that has access storage device 10. In such examples, reliability module 40 may receive the reliability information via host device interface 20.

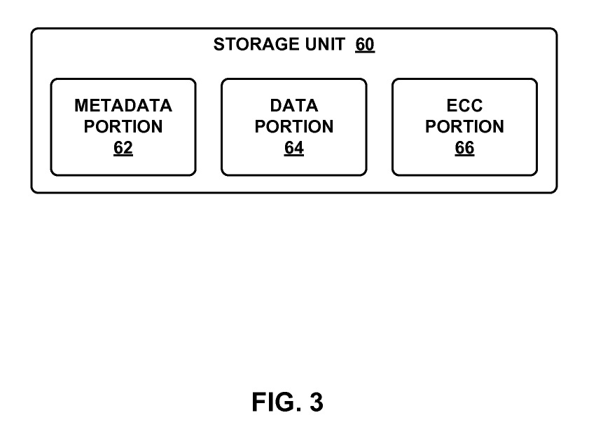

FIG. 3 is a conceptual diagram of an example storage unit 60 according one aspect of the present invention. In some examples, storage unit 60 may correspond to a storage unit contained in storage block 14. Storage unit 60 is configured to store and retrieve data in response to commands received from a controller. Such commands, in some examples may be issued by processor 16 of controller 12 in storage device 10 of FIG. 1.

Storage unit 60 includes metadata portion 62, data portion 64, and ECC portion 66. In some examples, metadata portion 62, data portion 64, and ECC portion 66 may correspond to metadata storage cells, data storage cells, and ECC storage cells within a flash memory device or solid state drive (SSD). Storage unit 62 may, in some examples, include a plurality of data blocks, each of which has a corresponding portion stored within metadata portion 62, data portion 64, and ECC portion 66 of storage unit 60.

Metadata portion 62 may store any data associated with storage unit 60 that does not belong to data portion 64 and/or ECC portion 66. For example, metadata portion 62 may include data that describes data block boundaries and/or provisioning of data blocks within data portion 64 and ECC portion 66. In additional examples, metadata portion 62 may include reliability information for storage unit 60 and/or data blocks within storage unit 60. For example, metadata portion 62 may store a number of erase and/or program cycles that have occurred with respect to storage unit 60 or with respect to particular data blocks within storage unit 60. As another example, metadata portion 62 may store statistics regarding read, write, erase, and program times with respect to storage unit 60 or with respect to particular data blocks within storage unit 60. As a further example, metadata portion 62 may store an error log and/or a number of errors that may have occurred with respect to storage unit 60 or with respect to particular data blocks within storage unit 60. In some examples, some or all of the data described above with respect to metadata portion may be stored externally to storage unit 60, e.g., in memory 18 of storage device 10 in FIG. 1.

Data portion 64 may store the data portions of logical blocks or codewords stored within storage unit 60. The data portion, in some examples, may generally correspond to the data received from a host device via host device interface 20 as part of a write or program operation.

ECC portion 66 may store parity bits or other redundant data that is used to perform error detection or correction during read operations. In some examples, the redundant bits stored in ECC portion 66 may be derived from bits or data stored within data portion 64. In some examples, ECC portion 66 may store parity bits that are generated by various error correcting codes such as, e.g., a Reed-Solomon error correction code, a Bose, Ray-Chaudhuri, Hocquenghem (BCH) code, a turbo code, and/or a low-density parity-check (LDPC) code.

In some examples, data portion 64 and ECC portion 66 of storage unit 60 may be dynamically allocable. For example, storage unit 60 may be capable of receiving commands that direct storage unit 60 to allocate additional or less storage space for data storage and/or ECC storage. Such commands may be issued, in some examples, by reliability module 40, e.g., via variable ECC output 48. For example, if reliability module 40 determines the age of storage unit 60 is above a threshold age or that the reliability of storage unit 60 is below a threshold reliability, reliability module 40 may direct storage unit 60 to dynamically increase storage space allocated to ECC portion 66, and decrease storage space allocated to data portion 64. In some examples, metadata portion 62 may be dynamically allocable in a similar fashion. By increasing the ratio of ECC storage capacity to the data storage capacity, the number of parity bits stored for a given number of data bits increases, thereby improving and/or maintaining the reliability of storage unit 60.

In some examples, one or more of metadata portion 62, data portion 64, and ECC portion 66 may have storage cell capacities that are dynamically adjustable. For example, storage unit 60 may be capable of receiving a command that directs storage unit 60 to increase or decrease the storage cell capacity (e.g., the number of bits stored within a single storage cell) for the storage cells. Such commands may be issued, in some examples, by reliability module 40, e.g., via variable alphabet output 50. For example, if reliability module 40 determines the age of storage unit 60 is above a threshold age or that the reliability of storage unit 60 is below a threshold reliability, reliability module 40 may direct storage unit 60 to dynamically decrease the storage cell capacity for storage cells within storage unit 60. In some examples, the storage cells may be floating gate transistors where the number of voltage levels, thresholds, and ranges associated with the cell may be adjusted. By reducing the storage cell capacity as the age of storage unit 60 increases, the noise margins for the floating gate transistor cells may be increased, thereby improving and/or maintaining the reliability of storage unit 60.

Although example storage unit 60 is illustrated in FIG. 3 as including metadata portion 62, data portion 64, and ECC portion 66, in other examples, storage unit 60 may include any combination of one or more of metadata portion 62, data portion 64, and ECC portion 66 without departing from the scope of this disclosure.

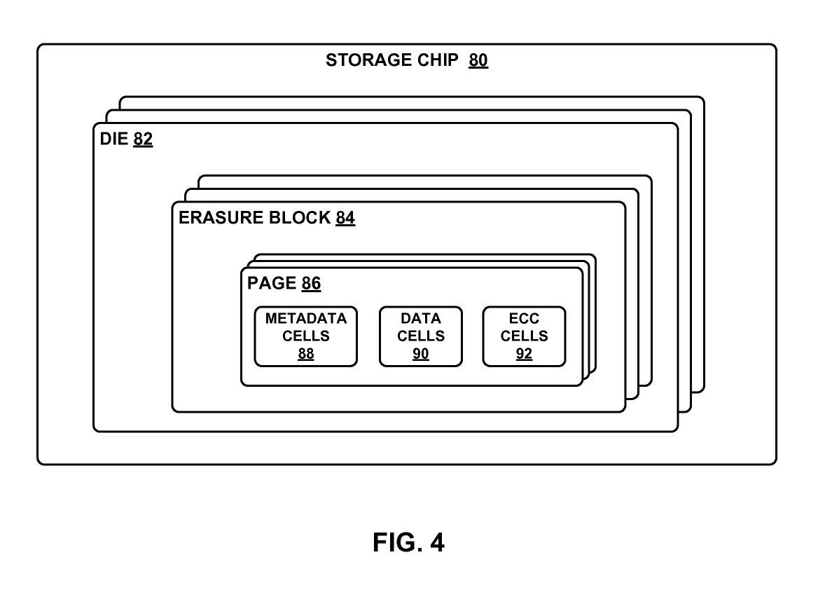

FIG. 4 is a conceptual diagram of an example storage chip 80 according to one aspect of the present invention. In some examples, storage chip 80 may correspond to storage unit 60 illustrated in FIG. 3. Storage unit 60 is configured to store and retrieve data in response to commands received from a controller. Such commands, in some examples may be issued by processor 16 of controller 12 in storage device 10 of FIG. 1.

Storage chip 80 includes one or more die 82. Each die 82 may, in some examples, correspond to a distinct piece of semiconductor upon which an integrated circuit is fabricated. Each die 82 includes or more erasure blocks 64. Each erasure block 84 may include a plurality of pages 86. Each page 86 may include a plurality of metadata cells 88, a plurality of data cells 90, and a plurality of ECC cells 92.

In some examples, the collection of metadata cells 88, data cells 90, and ECC cells 92 of page 86 may correspond, respectively, to metadata portion 62, data portion 64 and ECC portion 66 of storage unit 60 in FIG. 3. In additional examples, the metadata cells 88, data cells 90, and ECC cells 92 associated with multiple pages 86 in storage chip 80 may correspond, respectively, to metadata portion 62, data portion 64 and ECC portion 66 of storage unit 60 in FIG. 3.

In some examples, storage chip 60 may be a block storage device such as, e.g., a flash chip or a solid state drive (SSD). In such devices, a page 86 may constitute the smallest amount of data that can be read or written during a given read or program (e.g., write) operation. In other words, in such devices, page 86 may be the atomic data unit for read and program operations.

In additional examples, storage chip 80 may be an erase-before-write block storage device such as, e.g., a NAND flash chip or a NAND flash solid state drive (SSD). In such a device, before any data is overwritten in a storage cell, the storage cell must first be erased with an erasure operation separate from the write or program operation. Within such a device, each erasure block 84 may constitute the smallest amount of data that can be erased during a given erasure operation. In other words, in such devices, erasure block 84 may be the atomic data unit for erasure operations, and page 86 may be the atomic data unit for read and program operations.

In some examples, a data block may correspond to a particular page 86 within storage chip 80. In such examples, the data block may be the atomic data unit for read and program operations. In other examples, a data block may refer to a particular erasure block 84 within storage chip 80. In such examples, the data block may be the atomic data unit for erase operations. In further examples, a data block may refer to a particular die 82 within storage chip 80. In such examples, the data block may refer to a distinct semiconductor upon which data is stored. In additional examples, a data block may refer to a particular storage unit, e.g., storage chip 80.

Metadata cells 88 may store any data associated with page 86 that is not already stored in data cells 90 and/or ECC cells 92. As shown in FIG. 4, each page 86 may, in some examples, include metadata cells 88 that store information associated with the respective page 86. The metadata stored within metadata cells 88 may, in some cases, be identical or similar to the metadata described above with respect to metadata portion 62 in FIG. 3. For example, metadata cells 88 for a particular page 86 may store reliability information for the respective page 64, a number of erase and/or program cycles that have occurred for the respective page 64, statistics regarding read, write, erase, and program times for the respective page 64, an error log or number of errors that may have occurred for the respective page 86, and/or information related to the provisioning of data cells 90 and ECC cells 92 within the respective page 86.

In some examples, metadata cells 88 may not be associated with a particular page within an erasure block 84, but may be associated with the entire erasure block 84. In such examples, metadata cells 88 for a particular erasure block 84 may store reliability information for individual pages 86 within the respective erasure block 84, a number of erase cycles that have occurred for the respective erasure block 84, statistics regarding an amount of time to perform erase operations for the respective erasure block 84, a number of program cycles that have occurred for pages 86 within the respective erasure block, statistics regarding an amount of time to perform read and program operations for pages 86 within the respective erasure block 84, an error log or number of errors that may have occurred for the respective erasure block 84, information that describes page boundaries, and/or information related to the provisioning of data cells 90 and ECC cells 92 within pages 86 of the respective erasure block 84.

Data cells 90 may store the data portions of logical blocks or codewords stored within storage unit 60. The data stored within data cells 90 may, in some cases, be identical or similar to the metadata described above with respect to data portion 64 in FIG. 3. For example, the data stored in data cells 90 may generally correspond to the data received from a host device via host device interface 20 as part of a write or program operation.

ECC cells 92 may store parity bits or other redundant data that is used to perform error detection or correction during read operations. The data stored within ECC cells 92 may, in some cases, be identical or similar to the metadata described above with respect to ECC portion 66 in FIG. 3. For example, ECC cells 92 may store parity bits that are generated by various error correcting codes such as, e.g., a Reed-Solomon error correction code, a Bose, Ray-Chaudhuri, Hocquenghem (BCH) code, a turbo code, and/or a low-density parity-check (LDPC) code.

Although the example storage chip 80 shown in FIG. 4 includes multiple die 82, other storage chips may include only a single die. In addition, in some examples, erasure block 84 may only include a single page 86, which means that the atomic data unit for erase operations is identical to the atomic data unit for read and program operations. Various other combinations of data storage configurations for storage chip 80 are also contemplated and are within the scope of this disclosure.

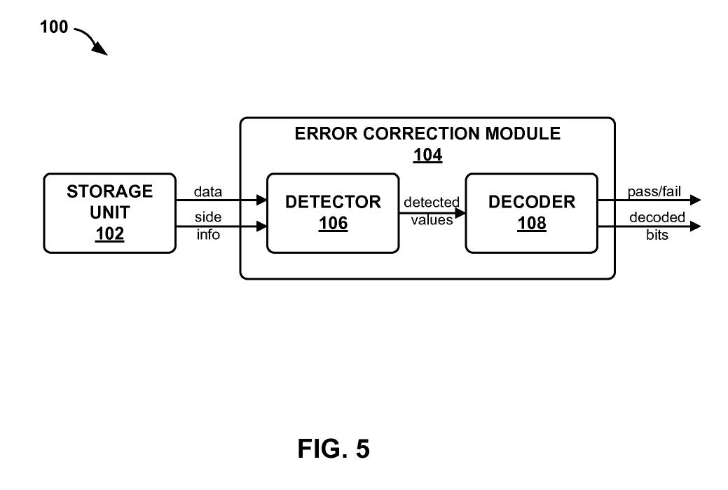

FIG. 5 is a block diagram of an example storage device 100 that includes an error correction module 104 according to one aspect of the present invention. Storage device 100 includes storage unit 102 and error correction module 104. In some examples, error correction module 104 may correspond to error correction module 26 of storage device 10 illustrated in FIG. 1.

Storage unit 102 is configured to store and retrieve data in response to commands received from controller 12. Storage unit 102 may retrieve raw data in response to instructions from controller 12, and output the raw data to detector 106.

The raw data, in some examples, may correspond to all or a portion of a codeword. As used herein, a codeword may refer to the combination of data bits and ECC bits associated with a logical block of data requested by a host device. A codeword, in some examples, may also refer to an ordering of binary bits designated by placeholders or digits. Some placeholders may be data bit placeholders and other placeholders may be ECC bit placeholders. A logical block, as used herein, may refer to the smallest unit of data that can be read from or written to storage device 10 by a host device.

In some examples, the raw data may be hard data. As used herein, hard data or hard information bits may refer to one or more bits retrieved from a storage cell where each possible logic value for the storage cell corresponds to at most one bit combination. In other words, for hard information bits, each logic value associated with a storage cell maps to a single bit combination. For example, for a single-level cell (SLC), hard data may correspond to a single bit that has two logic values (i.e., “0” or “1”). As another example, for a four-level multi-level cell (MLC), hard data may correspond to two bits that have four logic values (i.e., “00”, “01”, “10”, “11”).

As used herein, a logic level may correspond to a binary value that is derived from the codeword itself independent from the other factors connected to the physics of how the storage cells actually store the value. In examples where storage unit 62 uses floating gate transistors, hard data may be generated, for example, by comparing the voltage/current level read from the device to a set of thresholds. The number of thresholds, in some examples, may be equal to the number of logic values the cell is capable of storing minus one. In some examples, the hard data may include hard data associated with multiple cells.

In other examples the raw data may be soft data. As used herein, soft data or soft information bits may refer to a set of bits that includes hard information bits plus additional soft information bits. In examples where storage unit 62 uses floating gate transistors, soft data may be generated, for example, by comparing the voltage/current level read from the device to a set of thresholds. The number of thresholds, in some examples, may be greater than the number of logic values the cell is capable of storing minus one. In some examples, the soft data may include soft data associated with multiple cells.

Storage unit 102 may correspond, in some examples, to storage unit 60 shown in FIG. 3 or to storage chip 80 shown in FIG. 4. In additional examples, storage unit 102 may correspond to one or more data blocks within a storage device. In some examples, storage unit may correspond to a flash page, a flash erasure block, a flash die, a flash chip, a portion of a flash page, or the like. In additional examples, storage unit 102 may correspond to a storage block 14 of a storage device 10, such as, e.g., a solid state drive.

Error correction module 104 is configured to perform error correction on data retrieved from storage unit 102. Error correction module 104 may generate error correction information (e.g., a pass/fail indicator) and, in some examples, decoded bits. Error correction module 104 includes detector 106, and decoder 108.

Detector 106 is configured to generate detected values for a retrieved codeword based on the raw data received from storage unit 102 and side information. In some examples, detector 106 may be configured to generate a detected value for a bit within a portion of the codeword based on information related to a reliability of a data block associated with the respective codeword portion.

The side information may correspond to the reliability information discussed above with respect to FIG. 3 of this disclosure. As shown in FIG. 5, the side information may, in some examples, be provided by storage unit 102. In such examples, the reliability information may be stored, for example, in a metadata portion of the storage unit. In additional examples, the side information may be stored in and provided by memory 18 within controller 12 of storage device 10. In further examples, the side information may be provided by a host device through host device interface 20. In additional examples, the side information may be a reliability metric determined by reliability module 24. In yet further examples, the side information may be provided by a combination of the above-listed examples.

In any case, detector 106 uses the side information and raw data to generate detected values. In some examples, the detected values may be hard detected values. In other examples, the detected values may be soft detected values. In some examples, if decoder 108 is a hard decoder, then detector 106 may generate hard detected values. Similarly, if decoder 108 is a soft decoder, then detector 106 may generate soft detected values.

As used herein, hard detected values may refer to any combination of a binary one value (“1”), a binary value (“0”), and an erasure value (“E”). An erasure value indicates that detector 106 has determined that such bits were not properly received (i.e., were erased), and therefore no binary value is assigned to the digit. An erasure value acts as a placeholder within a codeword.

If the raw data received by detector 106 contains soft information, the hard detected values corresponding to the raw data will no longer include soft information bits. However, detector 106 may use the soft information bits in conjunction with the side information to determine the detected hard values.

If the raw data received by detector 106 contains only hard information, detector 106 may, in some examples, generate hard detected values based on the side information. In such examples, if detector 106 determines that the side information indicates an aging storage unit 62 or unreliable data, detector 106 may generate one or more erasure values for hard detected values.

As used herein, soft detected values may refer to any type of detected value that is not a hard detected value. In some examples, the soft detected values may include values determined based on probabilistic functions. For example, the soft detected values may include likelihood ratios or log-likelihood ratios (LLRs) for each of the placeholders or digits within the codeword. In some examples, each of the likelihood ratios may be calculated by determining the quotient of the probability of the digit being a one divided by the probability of the digit being a zero. A log-likelihood ratio may be calculated by performing a logarithm function on the likelihood ratio. The logarithm function may, in some examples, be a natural logarithm function. The probabilities may be conditioned on one or more of the hard information bits, soft information bits, and side information.

If the raw data received by detector 106 contains soft information, detector 106 may, in some examples, use the side information to saturate (e.g., increase) and/or attenuate (e.g., decrease) LLR values generated by detectors that generate LLRs based only on soft information, but not on side information. For example, if detector 106 determines that the side information indicates an aging storage unit 102 or unreliable data, detector 106 may attenuate the LLR. On the other hand, if detector 106 determines that the side information indicates an relatively new storage unit 102 or relatively reliable data, detector 106 may saturate the LLR.

In some examples, if the raw data received by detector 106 contains hard information, but not soft information, detector 106 may generate LLRs for digits within the codeword based on the raw data and the side information. For example, the side information may be a function of the position of the data cells within a page. In such cases, the side information may be used to generate position-specific LLRs for the codeword depending on the position of the digits within the page of the storage device.

In any case, detector 106 may generate detected values based on reliability information for a storage unit. For example, in storage devices where soft information is not already available, detector 106 may generate soft information for use by decoder 108. In cases where soft information is already available, detector 106 may modify the soft information (e.g., saturate or attenuate) based on the reliability information. In some examples, detector 106 may be incorporated into reliability module 40 in FIG. 2. In such examples, reliability module 40 may have a third output (not shown) that generates the detected values for a retrieved codeword.

In some examples, detector 106 may generate detected values based on time stamp information in addition to or in lieu of the side information discussed above in this disclosure. The time stamp information may include a time stamp that indicates how long data was stored within a particular data block or that indicates when data was programmed or written to a particular data block. In some storage devices, such as some flash devices for example, the longer the time for which data has been stored within a particular data block, the greater the amount of charge that is lost within the floating gate transistors. Because an increase in the amount of lost charge within a data block affects the accuracy of the retrieved data, a time stamp may be used as an indicator of data reliability in addition to the side information that includes indicators related to device aging. Thus, when detector 106 generates soft detected values, such as log-likelihood ratios for example, the time stamp may be used to increase or attenuate the log-likelihood ratios. The time stamp, in some examples, may be stored as metadata within the corresponding data block of the storage device, and may be provided by storage unit 102 to detector 106 in conjunction with the raw data for the data block.

Detector 106 may be implemented in hardware, software, or firmware. In some examples, detector 106 may be implemented as a lookup table (LUT). The LUT may, in some examples, be stored in a non-volatile memory such as, e.g., a Read-only Memory device (ROM).

Decoder 108 is configured to perform error correction on the detected values according to an error correction algorithm. In some examples, the error correction algorithm may include an error detection component and an error correction component. In other examples, the error correction algorithm may include an error detection component, but not an error correction component.

In some examples, the error correction algorithm may be an algebraic error correction algorithm. In such examples, decoder 108 may be referred to as a hard decoder. In other examples, the error correction algorithm may be a probabilistic error correction algorithm. In such examples, decoder 108 may be referred to as a soft decoder. Examples of error correction coding algorithms that may be used by decoder 108 include, e.g., a Reed-Solomon error correction code, a Bose, Ray-Chaudhuri, Hocquenghem (BCH) code, a turbo code, and/or a low-density parity-check (LDPC) code. Additional error correction coding algorithms are contemplated and are within the scope of this disclosure.

In any case, decoder 108 may generate error correction information based on the detected values and the error correction algorithm. The error correction information may, in some examples, relate to the results of the error detection/correction algorithm. For example, the error correction information may include a pass/fail indicator. The pass/fail indicator, in some examples, may indicate whether a threshold number of errors were detected when performing error correction on a codeword or portion of a codeword.

In some examples, decoder 108 may also generate decoded bits. The decoded bits may include an error corrected data portion of a codeword. In some examples, the decoded bits may be transmitted to a host device via host device interface 20.

The example error correction module 104 shown in FIG. 5 illustrates a detection technique that generates detected values based on reliability information. By utilizing detected values that are influenced by the sensed aging or degradation of a storage device, the performance of existing error correction decoders may be improved.

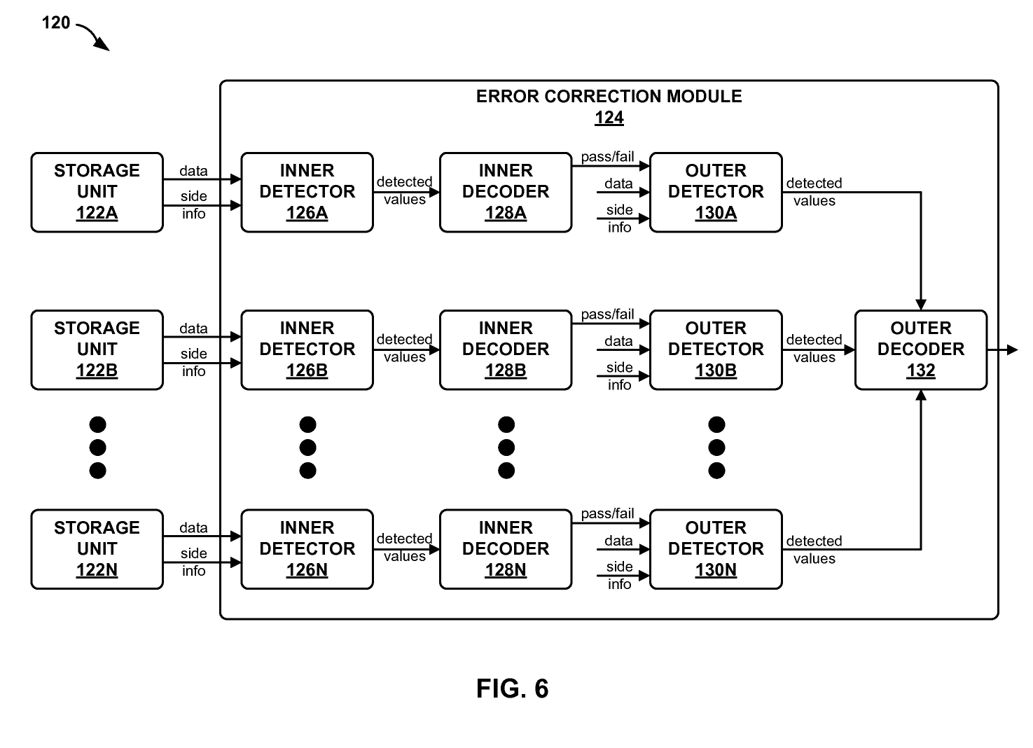

FIG. 6 is a block diagram of an example storage device 120 that includes an error correction module 124 according to one aspect of the present invention. Storage device 120 includes storage units 122A-122N (collectively “storage units 122”) and error correction module 124. In some examples, error correction module 124 may correspond to error correction module 26 of storage device 10 illustrated in FIG. 1.

Storage units 122 are configured to store and retrieve data in response to commands received from controller 12. In some examples, each of the storage units 122 in storage device 120 may correspond to an instance of storage unit 102 described above with respect to FIG. 5. Each of storage units 122 may correspond, in some examples, to storage unit 60 shown in FIG. 3 or to storage chip 80 shown in FIG. 4. In additional examples, each of storage units 122 may correspond to one or more data blocks within a storage device. In some examples, each of storage units 122 may correspond to a flash page, a flash erasure block, a flash die, a flash chip, or the like. In additional examples, each of storage units 122 may correspond to a storage block 14 of a storage device 10, such as, e.g., a solid state drive.

Storage units 122 may retrieve raw data in response to instructions from controller 12, and output the raw data to detectors 126. The raw data may be, in some examples, hard data or soft data. Storage units 122 may be further configured to transmit storage-unit specific side information related to data that is retrieved from storage units 122.

In some examples, storage units 122 may be configured to store a codeword. The codeword may be stored in a plurality of different data blocks. In such examples, the different data blocks may, in some examples, be located in different storage units. In other words, a codeword may be divided into codeword portions, each of which is stored within a different data block and/or storage unit 122.

Error correction module 124 is configured to perform error correction on data retrieved from storage units 122. Error correction module 124 may generate error correction information (e.g., a pass/fail indicator) and, in some examples, decoded bits. In some examples, error correction module 124 may correspond to error correction module 26 of storage device 10 illustrated in FIG. 1. Error correction module 124 includes inner detectors 126A-126N (collectively “inner detectors 126”), inner decoders 128A-128N (collectively “inner decoders 128”), outer detectors 130A-130N (collectively “outer detectors 130”), and outer decoder 132.

Error correction module 124 may include several components that are similar to components already described above with respect to error correction module 104 shown in FIG. 5. For example, each of inner detectors 126 may correspond to an instance of detector 106 described above with respect to FIG. 5. As another example, each of inner decoders 128 may correspond to an instance of decoder 108 described above with respect to FIG. 5.

Corresponding components may be constructed using the same or similar components and operate in a similar manner. Therefore, where the manner of construction or operation of corresponding components is similar, such details have not necessarily been repeated in the detailed description for FIG. 6.

Inner detectors 126 are configured to generate detected values for portions of a retrieved codeword based on the raw data received from storage unit 102. In some examples, inner detectors 126 may use side information in conjunction with the raw data to generate the detected values. In some examples, the detected values may be hard detected values (e.g., “1”, “0”, or “E”). In other examples, the detected values may be soft detected values (e.g., likelihood ratios or log-likelihood ratios (LLRs)).

In some examples, inner detectors 126 are configured to generate sets of detected values for the portions of the codeword based on information related to a respective reliability of each of the data blocks and/or storage units 122. Each set of detected values may correspond to a respective inner detector 126.

The side information may correspond to the reliability information discussed above with respect to FIG. 3 of this disclosure. In some examples, inner detectors 126 may generate detected values based on time stamp information in addition to or in lieu of the side information discussed above in this disclosure.

As discussed above with respect to FIG. 5, the side information may, in some examples, be provided by storage unit 102, memory 18 within controller 12 of storage device 10, a host device through host device interface 20, a reliability metric determined by reliability module 24, or by a combination of the above-listed examples.

Inner decoders 128 are configured to perform error correction on the detected values according to an error correction algorithm. Each of decoders 128 may be either a hard decoder or a soft decoder. If a particular one of decoders 128 is a hard decoder, then the corresponding one of the inner detectors 126, in some examples, is configured to generate hard detected values. Similarly, if a particular one of decoders 128 is a soft decoder, then the corresponding one of the inner detectors 126, in some examples, is configured to generate soft detected values.

In some examples, inner decoders 128 may be configured to perform codeword portion-specific error corrections on the portions of the codeword based on the detected values generated by inner detectors 126 to generate the codeword portion-specific error correction information. In some examples, inner decoders 128 may generate the codeword portion-specific error correction information based on the detected values and the error correction algorithm. The codeword portion-specific error correction information may, in some examples, relate to the results of the error detection/correction algorithm for a portion of the codeword stored within a particular storage unit 12 and/or a portion of the codeword stored within one or more particular data blocks. For example, the codeword portion-specific error correction information may include a pass/fail indicator for the respective codeword portion. The pass/fail indicator, in some examples, may indicate whether the error correction performed on the codeword portion was successful or not successful. For example, the pass/fail indicator may indicate a pass condition if the error correction algorithm was able to produce parity bits that match all of the parity bits within the respective codeword portion. On the other hand, the pass/fail indicator may indicate a fail condition if the error correction algorithm was not able to produce parity bits that match all of the parity bits within the respective codeword portion (e.g., if at least one parity bit does not match).

In some examples, inner decoders 128 may also generate decoded bits. The decoded bits may include an error-corrected data portion of a codeword. In some examples, the decoded bits may be transmitted to a host device via host device interface 20.

Outer detectors 130 are configured to generate detected values for portions of a retrieved codeword based on codeword-portion specific error correction information received from inner decoders 128. In some examples, each of outer detectors 130 may be configured to generate a respective set of detected values based on respective raw data received from a respective one of storage units 122 and respective codeword-portion specific error correction information received from a respective one of inner decoders 128. In such examples, each of outer detectors 130 may also use side information corresponding to a respective storage unit 122 corresponding to the raw data to generate the respective set of detected values.

In additional examples, each of outer detectors 130 may be configured to generate a respective set of detected values based on respective error-corrected data received from a respective one of inner decoders 128 and respective codeword-portion specific error correction information received from a respective one of inner decoders 128. In such examples, each of outer detectors 130 may also use side information corresponding to a respective storage unit 122 corresponding to the raw data to generate the respective set of detected values.

In some examples, the detected values may be hard detected values (e.g., “1”, “0”, or “E”). In other examples, the detected values may be soft detected values (e.g., likelihood ratio or log-likelihood ratio (LLR)).

In some examples, outer detectors 130 are configured to generate sets of detected values based on information related to a respective reliability for data blocks associated with storage units 122. Each set of detected values may correspond to a respective outer detector 128. In further examples, outer detectors 130 may be configured to generate a detected value for a bit within a portion of the codeword based on information related to a reliability of a data block associated with the respective portion.

The side information may correspond to the reliability information discussed above with respect to FIG. 3 of this disclosure. In some examples, outer detectors 130 may generate detected values based on time stamp information in addition to or in lieu of the side information discussed above in this disclosure.

As discussed above with respect to FIG. 5, the side information may, in some examples, be provided by storage unit 102, memory 18 within controller 12 of storage device 10, a host device through host device interface 20, a reliability metric determined by reliability module 24, or by a combination of the above-listed examples

Outer decoder 132 is configured to perform codeword-level error correction on the codeword based on the codeword-specific error correction information and based on the detected values generated by outer detectors 130. Outer decoder 132 may be configured to perform the codeword-level error correction on the detected values according to an error correction algorithm.

Outer decoder 132 may be either a hard decoder or a soft decoder. If outer decoder 132 is a hard decoder, then each of outer detectors 130, in some examples, may be configured to generate hard detected values. Similarly, outer decoder 132 is a soft decoder, then each of outer detectors 130, in some examples, is configured to generate soft detected values.

In some examples, outer decoder 132 may perform error correction on a codeword based on sets of detected values generated by outer detectors 128. In additional examples, outer decoder 132 may be configured to perform error correction on a second portion of the codeword based on the detected value for the bit within the first portion of the codeword.

Outer decoder 132 may generate decoded bits. The decoded bits may include an error corrected data portion of a codeword. In some examples, the decoded bits may be transmitted to a host device via host device interface 20.

The example error correction module 124 shown in FIG. 6 illustrates a detection technique that generates detected values based on reliability information associated with particular storage units or devices. In some cases, the storage units may correspond to individual data blocks, flash chips, flash die, or flash devices.

In some examples, when a logical block is inter-dispersed across multiple Flash chips (e.g., an interleaved architecture used to improve performance or reliability), the reliability information may be used to identify Flash devices that are aging faster than others. In some examples, device-specific p/e times may be used to differentiate levels of aging between the devices. In additional examples, any of the reliability information described herein may be used identify devices that are aging faster than others.

In the example error correction unit 124 of FIG. 6, the storage unit-specific detectors (126, 130) may be used to assign a low reliability to the soft detected values of codeword portions that are read from the less reliable devices (e.g., attenuate the LLR), and assign a high reliability to soft detected values of codeword portions that are read from more reliable devices (e.g., increase/saturate the LLR). In this manner, outer decoder 132 may utilize the device-specific soft detected values to improve the detection and correction of errors.

In some examples, inner detectors 126 may generate soft detected values, and outer detectors 130 may generate hard detected values. In such examples, inner decoder 128 may be a soft decoder (e.g., an LDPC decoder) and outer decoder 132 may be a hard decoder 132 (e.g., a Reed-Solomon decoder).

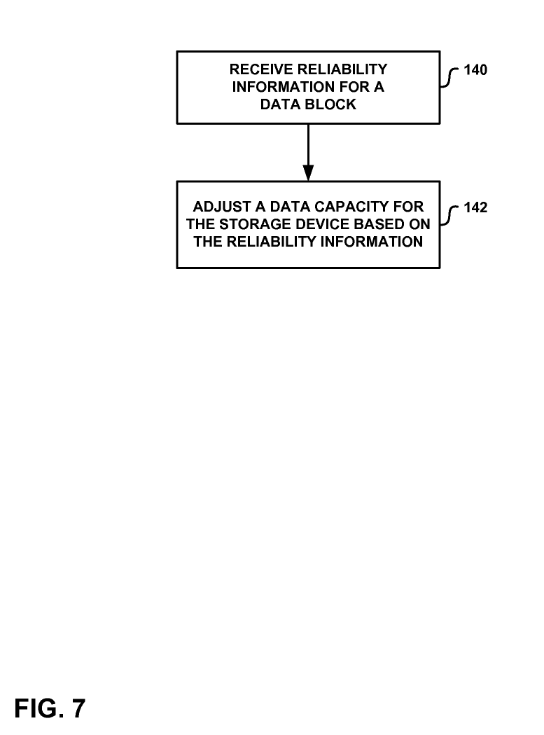

FIG. 7 is a flow diagram illustrating an example method for adjusting a data capacity of a storage device based on reliability information according to one aspect of the present invention. Reliability module 24 may receive information related to a reliability of a data block within the storage device (e.g., reliability information) (140). Reliability module 24 may adjust a data capacity for the storage device based on the information related to the reliability of the data block (142). In some examples, reliability module 24 may adjust a data capacity for one or more particular storage units within the storage device based on the information related to the reliability of the data block.

Reliability module 24 may, in some examples, adjust the data capacity at least in part by adjusting a raw data capacity. For example, reliability module 24 may allocate additional physical storage space (e.g., blocks or portions thereof) to each logical block.

In some examples, the information related to the reliability of the data block may include an amount of time to perform an erase operation for the data block and/or an amount of time to perform a program operation for the data block. The data block, in some examples, may be a flash erasure block and/or a flash page.

In some examples, reliability module 24 may adjust the capacity of the data block by adjusting an ECC code rate for the data block. For example, reliability module 24 may reallocate one or more data storage cells within the storage device to operate as error correction storage cells to reduce the ECC code rate.

In additional examples, reliability module 24 may adjust the capacity of the data block by adjusting an alphabet size for storage cells within the data block. For example, reliability module 24 may use only a subset of the maximum alphabet size of a multi-level cell (MLC) block storage device.

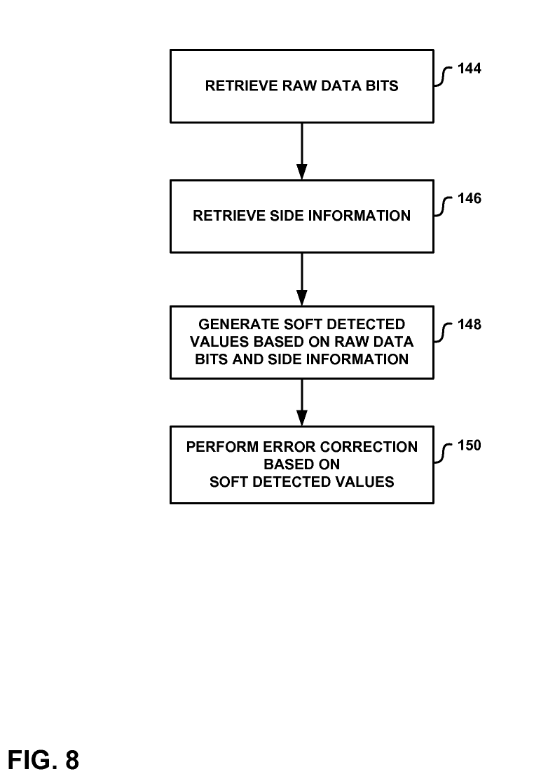

FIG. 8 is a flow diagram illustrating an example method for performing error correction based on reliability information according to one aspect of the present invention. Error correction module 26 may retrieve raw data bits for a codeword (e.g., a logical data block) (144). In some examples, the raw data bits may include soft information bits.

Error correction module 26 may retrieve side information for the codeword (146). In some examples, error correction module 26 may retrieve side information that is specific to a particular portion of a codeword, e.g., side information specific to a portion of codeword retrieved from a particular storage device or storage unit. In additional examples, error correction module 26 may retrieve side information for an entire codeword.

In some examples, the side information may include an amount of time to perform an erase operation for the data block and/or an amount of time to perform a program operation for the data block. In additional examples, the side information may include errors that occur with respect to the data block and/or an error log for the data block. The data block, in some examples, may be a flash erasure block and/or a flash page.

Error correction module 26 may generate soft detected values for the raw data bits based on soft information bits contained within the raw data bits and the reliability information (148). In some examples, error correction module 26 may increase or decrease a probabilistic value, such as a log-likelihood ratio (LLR) for example, based on the reliability information to generate reliability-sensitive soft information (i.e., the soft detected values).

Error correction module 26 may perform error correction on the raw data bits based on the soft detected values (150). In one example, error correction module 46 may use the reliability-sensitive soft information to perform a message-passing algorithm, for example, an LDPC message passing algorithm.

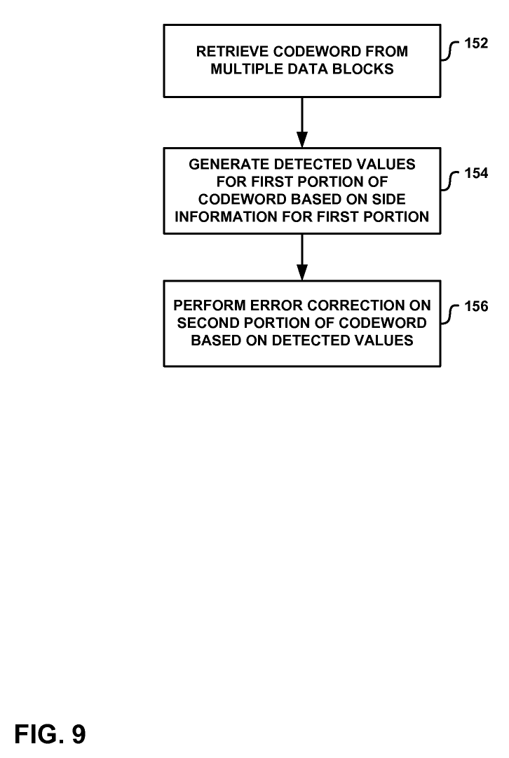

FIG. 9 is a flow diagram illustrating an example method for performing error correction based on reliability information according to one aspect of the present invention. Error correction module 26 may retrieve a codeword from multiple data blocks within a storage device. Each of the data blocks may store a respective portion of the codeword (152). Error correction module 26 may generate a detected value for a bit within a first portion of the codeword based on information related to a reliability of a data block associated with the first portion (154). Error correction module 26 may perform error correction on a second portion of the codeword based on the detected value for the bit within the first portion of the codeword (156).

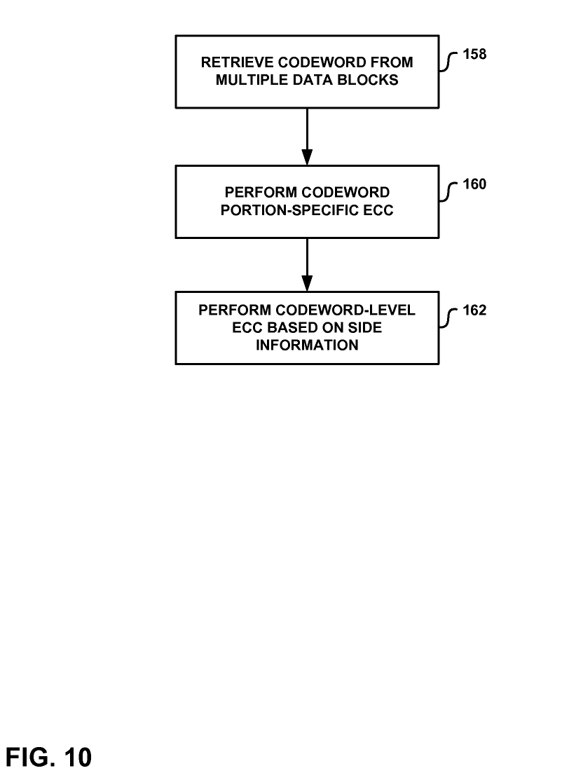

FIG. 10 is a flow diagram illustrating an example method for performing error correction based on reliability information according to one aspect of the present invention. Error correction module 26 may retrieve a codeword from multiple data blocks within a storage device (158). Each of the data blocks stores a respective portion of the codeword. Error correction module 26 may perform codeword portion-specific error corrections on the portions of the codeword to generate codeword portion-specific error correction information (160). In some examples, the codeword portion-specific error correction information may include a pass/fail indicator that indicates whether the specific codeword portion passed or failed the error correction procedure.

Error correction module 26 may perform codeword-level error correction on the codeword based on the codeword-specific error correction information and information related to a reliability of each of the data blocks (162). In some examples, error correction module 26 may perform the codeword-level error correction by performing error correction on a first portion of a codeword retrieved from a first storage unit based on reliability information or error correction information generated for a second portion of the codeword retrieved from a second storage unit. In additional examples, error correction module 26 may perform the codeword-level error correction by performing error correction on a first portion of a codeword retrieved from a first storage unit based on codeword portion-specific error correction information generated for a second portion of the codeword retrieved from a second storage unit.

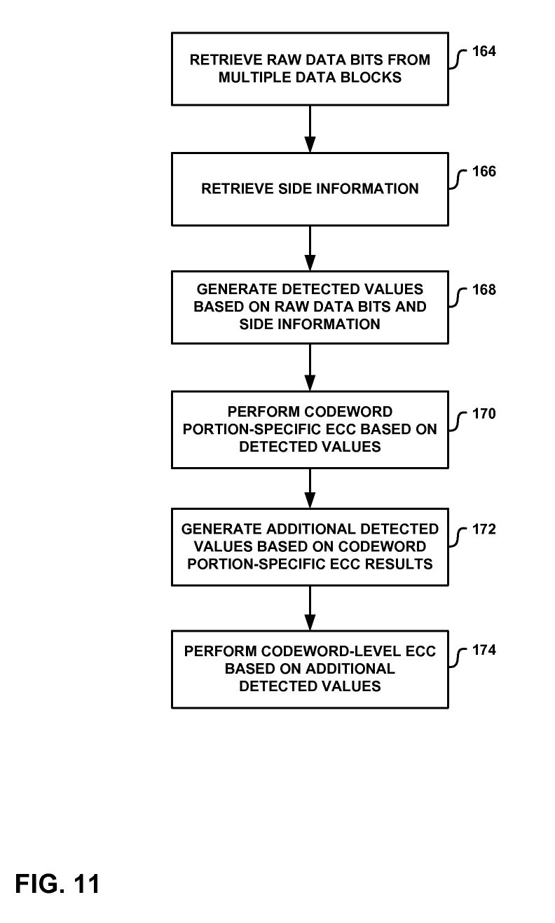

FIG. 11 is a flow diagram illustrating an example method for performing error correction based on reliability information according to one aspect of the present invention. Error correction module 26 may retrieve raw data bits for a codeword (e.g., a logical data block) stored within multiple storage units (164). In some examples, the multiple storage units may be multiple flash chips or flash die. The raw data bits may, in some examples, include hard information bits or soft information bits. The hard information bits may, in some examples, include only one bit for each placeholder or binary digit within the codeword. The soft information bits may include hard information bits and additional bits. The additional bits may provide a greater degree of granularity in the voltage and/or current levels read from the storage cells. Such additional bits may provide belief information or likelihood information that the hard information bits actually represent the purported data value indicated by the hard information bits.

Error correction module 26 may retrieve side information for the codeword (166). In some examples, error correction module 26 may retrieve side information that is specific to a particular portion of a codeword, e.g., side information specific to a portion of codeword retrieved from a particular storage device or storage unit.

In some examples, the side information may include an amount of time to perform an erase operation for the data block and/or an amount of time to perform a program operation for the data block. In additional examples, the side information may include errors that occur with respect to the data block and/or an error log for the data block. In further examples, the side information may include a number of erase operations that have occurred for a particular data block and/or a number of program operations that have occurred for a particular data block. The data block, in some examples, may be a flash erasure block and/or a flash page.

Error correction module 26 may generate detected values for the raw data bits based on the raw data bits and the side information (168). In some examples, error correction module 26 may generate the detected values based on the raw data bits independently of the side information. In some examples, the detected values may be hard data values (e.g., binary “1”, binary “0”, erasure “E”). In additional examples, the detected values may be soft detected values (e.g., log-likelihood ratios (LLRs)).

Error correction module 26 may perform codeword portion-specific error corrections on the portions of the codeword to generate codeword portion-specific ECC results (170). Such results may, in some examples, include a pass/fail indicator. In some examples, error correction module 26 may perform algebraic error detection/correction. In additional examples, error correction module 26 may perform probabilistic error detection/correction.

Error correction module 26 may generate additional detected values based on the codeword portion-specific ECC results (172). Such additional detected values may be hard-detected values or soft-detected values. Error correction module 26 may perform codeword-level ECC based on the additional detected values (174).

The techniques described in this disclosure may be implemented within one or more of a general purpose microprocessor, digital signal processor (DSP), application specific integrated circuit (ASIC), field programmable gate array (FPGA), programmable logic devices (PLDs), or other equivalent logic devices. Accordingly, the terms “processor” or “controller,” as used herein, may refer to any one or more of the foregoing structures or any other structure suitable for implementation of the techniques described herein.

The various components illustrated herein may be realized by any suitable combination of hardware, software, firmware, or any combination thereof. In the figures, various components are depicted as separate units or modules. However, all or several of the various components described with reference to these figures may be integrated into combined units or modules within common hardware, firmware, and/or software. Accordingly, the representation of features as components, units or modules is intended to highlight particular functional features for ease of illustration, and does not necessarily require realization of such features by separate hardware, firmware, or software components. In some cases, various units may be implemented as programmable processes performed by one or more processors.

Any features described herein as modules, devices, or components may be implemented together in an integrated logic device or separately as discrete but interoperable logic devices. In various aspects, such components may be formed at least in part as one or more integrated circuit devices, which may be referred to collectively as an integrated circuit device, such as an integrated circuit chip or chipset. Such circuitry may be provided in a single integrated circuit chip device or in multiple, interoperable integrated circuit chip devices, and may be used in any of a variety of image, display, audio, or other multi-media applications and devices. In some aspects, for example, such components may form part of a mobile device, such as a wireless communication device handset.

If implemented in software, the techniques may be realized at least in part by a computer-readable data storage medium comprising code with instructions that, when executed by one or more processors, performs one or more of the methods described above. The computer-readable storage medium may form part of a computer program product, which may include packaging materials. The computer-readable storage medium may comprise random access memory (RAM) such as synchronous dynamic random access memory (SDRAM), read-only memory (ROM), non-volatile random access memory (NVRAM), electrically erasable programmable read-only memory (EEPROM), embedded dynamic random access memory (eDRAM), static random access memory (SRAM), flash memory, magnetic or optical data storage media. Any software that is utilized may be executed by one or more processors, such as one or more DSP's, general purpose microprocessors, ASIC's, FPGA's, or other equivalent integrated or discrete logic circuitry.

The implementations described above and other implementations are within the scope of the following claims.

1. A method comprising:
retrieving a codeword from a plurality of data blocks within a storage device, wherein each of the data blocks stores a respective portion of the codeword;
generating a detected value for a bit within a first portion of the codeword based on information related to a reliability of a data block associated with the first portion; and
performing error correction on a second portion of the codeword based on the detected value for the bit within the first portion of the codeword.

2. The method of claim 1, wherein the detected value comprises a hard detected value.

3. The method of claim 1, wherein the detected value comprises a soft detected value.

4. The method of claim 3, wherein the soft detected value comprises a value generated based on a probabilistic function.

5. The method of claim 3, wherein the soft detected value comprises a log-likelihood ratio (LLR).

6. The method of claim 1, further comprising:
generating sets of detected values based on information related to a respective reliability for each of the data blocks, wherein each set of detected values includes detected values associated with a respective portion of the codeword; and
performing error correction on the second portion of the codeword based on the sets of detected values.

7. The method of claim 6, further comprising:
performing codeword portion-specific error corrections on the portions of the codeword to generate codeword portion-specific error correction information,
wherein generating the sets of detected values comprises generating the sets of detected values based on information related to the respective reliability for each of the data blocks and the codeword portion-specific error correction information.

8. The method of claim 7,
wherein the sets of detected values are a first group of detected values,
wherein the method further comprises generating a second group of detected values for the portions of the codeword based on information related to a respective reliability of each of the data blocks, and
wherein performing the codeword portion-specific error corrections comprises performing codeword portion-specific error corrections on the portions of the codeword based on the second group of detected values to generate the codeword portion-specific error correction information.

9. The method of claim 6, wherein performing the error correction on the second portion of the codeword comprises:
performing codeword portion-specific error corrections on the portions of the codeword to generate codeword portion-specific error correction information; and
performing the error correction on the second portion based on codeword portion-specific error correction information associated with the first portion of the codeword.

10. The method of claim 1, wherein each of the data blocks is associated with a respective storage chip within a plurality of storage chips.

11. The method of claim 1, wherein the codeword is a logical block requested by a host device.

12. The method of claim 1, wherein the information related to the reliability of the each of the data blocks comprises information related to at least one of an erase cycle count for a data block or a program cycle count for a data block.

13. The method of claim 1, wherein the information related to the reliability of the each of the data blocks comprises information related to at least one of an amount of time to perform an erase operation for a data block and an amount of time to perform a program operation for a data block.

14. The method of claim 1, wherein the information related to the reliability of the each of the data blocks comprises information related to at least one of errors that occur with respect to a data block and an error log for a data block.

15. A method comprising:
retrieving a codeword from a plurality of data blocks within a storage device, wherein each of the data blocks stores a respective portion of the codeword;
performing codeword portion-specific error corrections on the portions of the codeword to generate codeword portion-specific error correction information; and
performing codeword-level error correction on the codeword based on the codeword-specific error correction information and information related to a reliability of each of the data blocks.

16. The method of claim 15, wherein each of the data blocks is associated with a respective storage chip within a plurality of storage chips.

17. A method comprising:
retrieving raw data bits for a codeword stored within a data block of a block storage device;
retrieving information related to a reliability of the data block, wherein the information related to the reliability of the data block comprises at least of an amount of time to perform an erase operation for the data block, an amount of time to perform a program operation for the data block, errors that occur with respect to the data block, and an error log for the data block;
generating soft detected values for the raw data bits based on soft information bits contained within the raw data values and information related to a reliability of the data block; and
performing error correction for the raw data bits based on the soft detected values.

18. The method of claim 17, wherein the soft detected values comprise log-likelihood ratios (LLR).

19. The method of claim 17, wherein the information related to the reliability of the each of the data blocks comprises information related to at least one of an amount of time to perform an erase operation for a data block and an amount of time to perform a program operation for a data block.

20. The method of claim 17, wherein the information related to the reliability of the each of the data blocks comprises information related to at least one of errors that occur with respect to a data block and an error log for a data block.

21-50. (canceled)
